(19) United States
(12) Patent Application Publication
(10) Pub. No.: US 2015/0171233 A1
(43) Pub. Date: Jun. 18, 2015

(54) ULTRAVIOLET SENSOR, ULTRAVIOLET SENSING APPARATUS, AND SENSING METHOD FOR OBTAINING COMPENSATED ULTRAVIOLET SENSING RESULT

(71) Applicant: EMINENT ELECTRONIC TECHNOLOGY CORP. LTD., Hsinchu (TW)

(72) Inventors: TOM CHANG, Taipei City (TW); Kao-Pin Wu, New Taipei City (TW); Shang-Ming Hung, Hsinchu County (TW); Chih-Jen Fang, Tainan City (TW); Yu-Bin Lin, Changhua County (TW)

(21) Appl. No.: 14/564,112

(22) Filed: Dec. 9, 2014

Related U.S. Application Data
(60) Provisional application No. 61/915,478, filed on Dec. 12, 2013.

(30) Foreign Application Priority Data
Nov. 5, 2014 (TW) 103138388

(51) Int. Cl. H01L 31/0216; G01J 5/20; H01L 31/103; G01J 1/42

(52) U.S. Cl. CPC H01L 31/02162; G01J 1/429; G01J 1/4204; G01J 5/20; H01L 31/103

(57) ABSTRACT

An ultraviolet sensor includes a p-type doping substrate, an n-type doping region and an ultraviolet pass filter layer. The n-type doping region is formed on a surface of the p-type doping substrate. The ultraviolet pass filter layer is disposed in correspondence with the n-type doping region. The n-type doping region is located between the ultraviolet pass filter layer and the p-type doping substrate. An ultraviolet sensing apparatus includes an ultraviolet sensor, an auxiliary light sensor and a processing circuit. The ultraviolet sensor generates an ultraviolet sensing result in response to surrounding light. The auxiliary light sensor generates an auxiliary light sensing result in response to the surrounding light. The auxiliary light sensor and the ultraviolet sensor have different detection wave ranges. The processing circuit performs manipulation upon the auxiliary light sensing result according to the ultraviolet sensing result, and accordingly obtains a compensated ultraviolet sensing result.

### CROSS REFERENCE TO RELATED APPLICATIONS

This application claims the benefit of U.S. provisional application No. 61/915,478, filed on Dec. 12, 2013, the contents of which are incorporated herein by reference.

### BACKGROUND OF THE INVENTION

1. Field of the Invention

The disclosed embodiments of the present invention relate to ultraviolet sensing, and more particularly, to an ultraviolet sensor which absorbs short wavelength light and filters out ambient light and infrared light, and a related ultraviolet sensing apparatus and a sensing method for obtaining a compensated ultraviolet sensing result.

2. Description of the Prior Art

Excessive exposure to ultraviolet (UV) radiation may result in chronic harmful effects on the skin, eye and immune system. To track intensity of UV radiation in the environment to thereby take related protective measures, a UV sensor is utilized to acquire UV light information in the environment. However, conventional UV sensors involve a complicated fabrication process and high costs, and are not conveniently portable due to their large sizes. Hence, a user will not carry a UV sensor with himself/herself and thus is unable to obtain the UV light information in the environment at any time.

Thus, a novel UV sensor, which may have a small size and achieve high quality measurement, is needed to facilitate tracking the UV radiation intensity at any time.

### SUMMARY OF THE INVENTION

It is therefore one objective of the present invention to provide an ultraviolet sensor which absorbs short wavelength light and filters out ambient light and infrared light, and a related ultraviolet sensing apparatus and a sensing method for obtaining a compensated ultraviolet sensing result to solve the above problems.

According to an embodiment of the present invention, an exemplary ultraviolet sensor is disclosed. The exemplary ultraviolet sensor comprises a p-type doping substrate, an n-type doping region and an ultraviolet pass filter layer. The n-type doping region is formed on a surface of the p-type doping substrate. The ultraviolet pass filter layer is disposed in correspondence with the n-type doping region, wherein the n-type doping region is located between the ultraviolet pass filter layer and the p-type doping substrate.

According to an embodiment of the present invention, an exemplary ultraviolet sensing apparatus is disclosed. The exemplary ultraviolet sensing apparatus comprises an ultraviolet sensor, an auxiliary light sensor and a processing circuit. The ultraviolet sensor is arranged for generating an ultraviolet sensing result in response to surrounding light. The auxiliary light sensor is arranged for generating an auxiliary light sensing result in response to the surrounding light, wherein a detection wave range of the auxiliary light sensor is different from a detection wave range of the ultraviolet sensor. The processing circuit is coupled to the ultraviolet sensor and the auxiliary light sensor, and is arranged for performing a manipulation upon the auxiliary light sensing result according to the ultraviolet sensing result, and accordingly obtaining a compensated ultraviolet sensing result.

According to an embodiment of the present invention, an exemplary sensing method for obtaining a compensated ultraviolet sensing result is disclosed. The exemplary sensing method comprises the following steps: utilizing an ultraviolet sensor to generate an ultraviolet sensing result in response to surrounding light; utilizing an auxiliary light sensor to generate an auxiliary light sensing result in response to the surrounding light, wherein a detection wave range of the auxiliary light sensor is different from a detection wave range of the ultraviolet sensor; and performing a manipulation upon the auxiliary light sensing result according to the ultraviolet sensing result, and accordingly obtaining the compensated ultraviolet sensing result.

The proposed UV sensing architecture not only involves a simple fabrication process but also can be integrated with other devices easily. Additionally, the proposed UV sensing architecture may have excellent sensitivity. Thus, the proposed UV sensing architecture may be employed in a variety of electronic products and/or personal portable apparatuses.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a cross-section view of an exemplary ultraviolet sensor according to an embodiment of the present invention.

FIG. 2 is a cross-section view of an implementation of the ultraviolet sensor shown in FIG. 1.

FIG. 3 is a cross-section view of an implementation of the ultraviolet sensor shown in FIG. 1.

FIG. 4 is a cross-section view of an implementation of the ultraviolet sensor shown in FIG. 1.

FIG. 5 is a cross-section view of an implementation of the ultraviolet sensor shown in FIG. 1.

FIG. 6 is a cross-section view of an implementation of the ultraviolet sensor shown in FIG. 1.

FIG. 7 is a cross-section view of an implementation of the ultraviolet sensor shown in FIG. 1.

FIG. 8 illustrates a sensor spectrum of an exemplary ultraviolet sensor according to an embodiment of the present invention.

FIG. 9 is a block diagram illustrating an exemplary ultraviolet sensing apparatus according to an embodiment of the present invention.

FIG. 10 is a diagram illustrating determination of an ultraviolet sensing parameter and an auxiliary light sensing parameter according to an embodiment of the present invention.

### DETAILED DESCRIPTION

The proposed UV sensing architecture may be implemented at a wafer level, and may reduce/eliminate interference from non-UV light (e.g. ambient light or infrared light). Further description is described below.

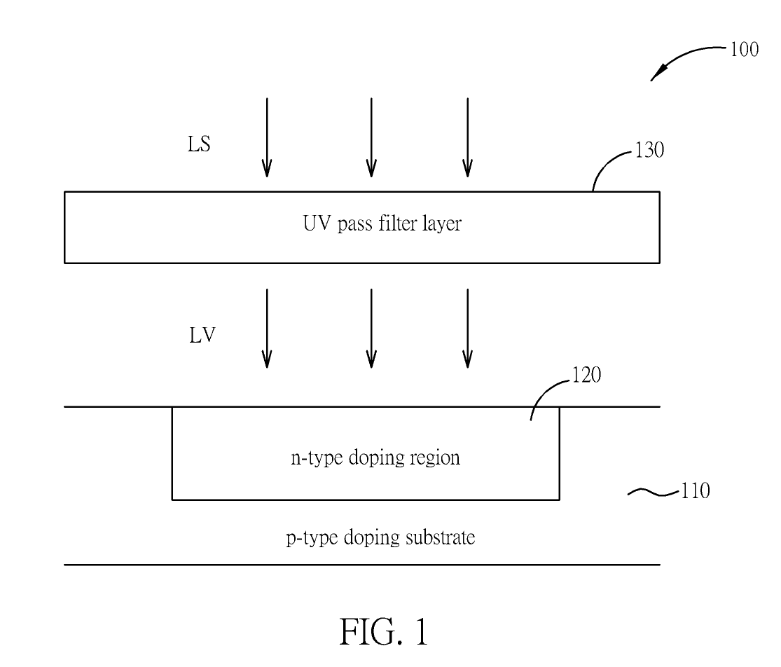

Please refer to FIG. 1, which is a cross-section view of an exemplary ultraviolet (UV) sensor according to an embodiment of the present invention. The UV sensor 100 may include, but is not limited to, a p-type doping substrate 110, an n-type doping region 120 and an ultraviolet (UV) pass filter layer 130 (e.g. a UV bandpass filter layer). In this embodiment, the n-type doping region 120 may be formed on a surface of the p-type doping substrate 110, wherein a PN junction formed between the p-type doping substrate 110 and the n-type doping region 120. In other words, a photodiode (or a photonic detector) architecture may be implemented by forming the n-type doping region 120 on the surface of the p-type doping substrate 110.

The UV pass filter layer 130 is disposed in correspondence with the n-type doping region 120, wherein the n-type doping region 120 is located between the UV pass filter layer 130 and the p-type doping substrate 110. When surrounding light LS is incident to the UV sensor 100, the UV pass filter layer 130 may filter out non-UV components of the surrounding light LS (i.e. allowing a UV component of the surrounding light LS (UV light LV) to pass through the UV pass filter layer 130). Accordingly, the PN junction between the p-type doping substrate 110 and the n-type doping region 120 may generate a UV sensing result in response to the UV light LV.

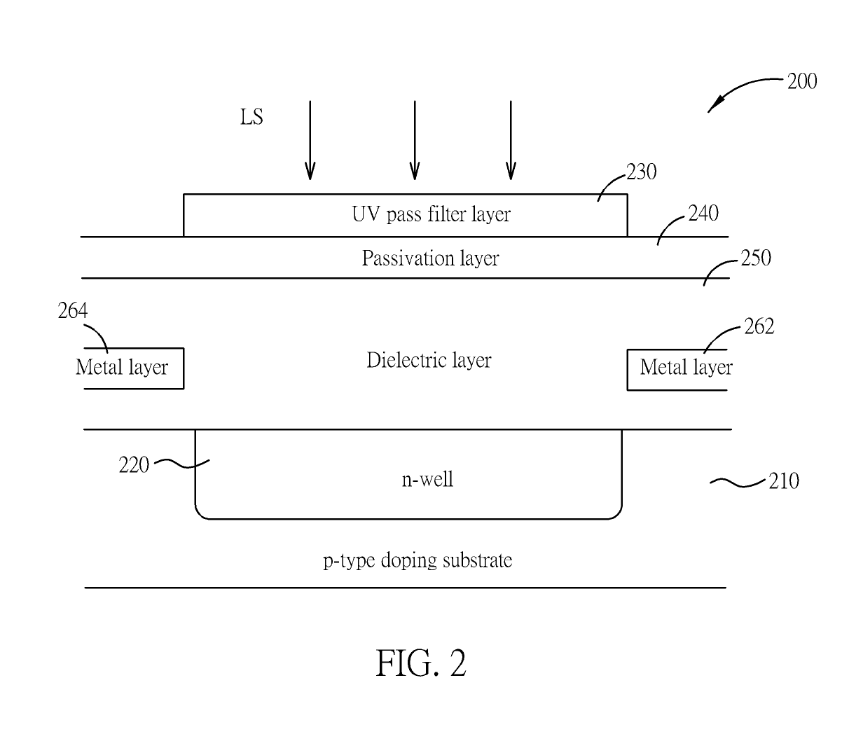

It should be noted that the UV sensing architecture shown in FIG. 1 may be implemented at a wafer level. Hence, the proposed UV sensing architecture may involve a simple fabrication process and have low costs, and can be integrated with other devices easily. Additionally, the n-type doping region 120 may be implemented in various manners in response to different requirements. Please refer to FIG. 2, which is a cross-section view of an implementation of the UV sensor 100 shown in FIG. 1. The UV sensor 200 may include a p-type doping substrate 210, an n-well 220 and a UV pass filter layer 230, wherein the p-type doping substrate 110, the n-type doping region 120 and the UV pass filter layer 130 shown in FIG. 1 maybe implemented by the p-type doping substrate 210, the n-well 220 and the UV pass filter layer 230, respectively. The UV sensor 200 may further include a passivation layer 240, a dielectric layer 250 (implemented by silicon dioxide in this implementation), a metal layer 262 and a metal layer 264. The passivation layer 240 may be used to prevent a wafer from physical or chemical damages (e.g. a waterproof and/or corrosion-resistant layer), and the dielectric layer 250 may be used to provide electrical insulation. In this implementation, the UV pass filter layer 230 may be formed on the passivation layer 240, and the dielectric layer 250 maybe formed between the passivation layer 240 and the p-type doping substrate 210.

Please note that the above stack structure is for illustrative purposes only, and is not meant to be a limitation of the present invention. As long as the dielectric layer 250 is located between the UV pass filter layer 230 and the p-type doping substrate 210, the sensing architecture may be implemented in various manners. In an alternative design, the UV pass filter layer 230 may be coated/formed on the dielectric layer 25. Next, the passivation layer 240 may be formed to cover the UV pass filter layer 230. In another alternative design, the passivation layer 240 may be omitted. Further, the dielectric layer 250 maybe omitted, and the UV pass filter layer 230 may be coated/formed directly on the p-type doping substrate 210 (the n-well 220).

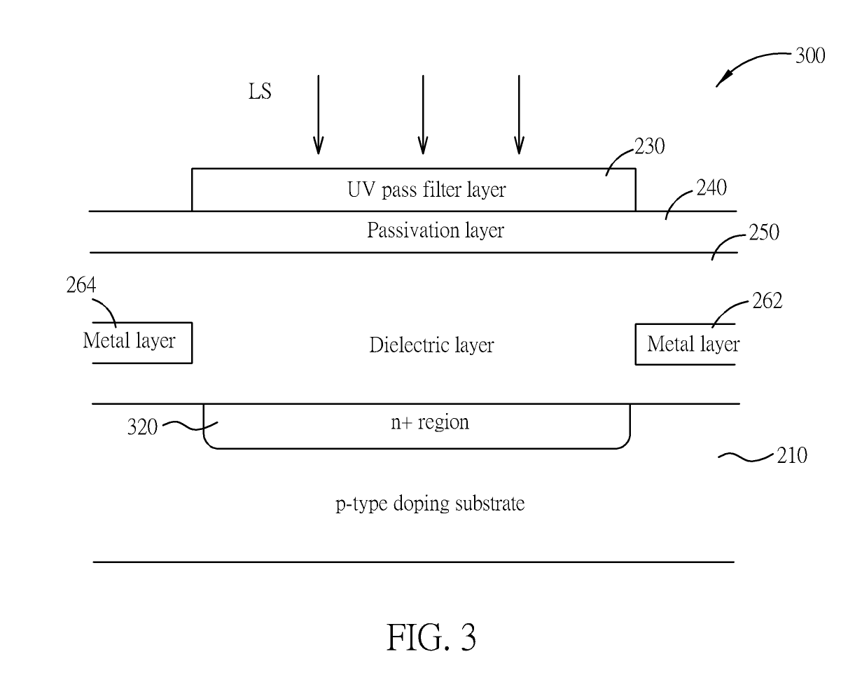

The n-type doping region 120 shown in FIG. 1 is not limited to the n-well 220 shown in FIG. 2. Please refer to FIG. 3, which is a cross-section view of an implementation of the UV sensor 100 shown in FIG. 1. The architecture of the UV sensor 300 shown in FIG. 3 is based on the architecture of the UV sensor 200 shown in FIG. 2, wherein the main difference is that the UV sensor 300 may include an n+ region 320 used to replace the n-well 220 shown in FIG. 2. As a doping concentration of the n+ region 320 is high, a doping depth thereof is shallow, which shortens a travel path of UV light from dielectric layer 250 to a PN junction between the p-type doping substrate 210 and the n+ region 320. Hence, UV absorption (UV sensitivity) of the UV sensor 300 may be increased.

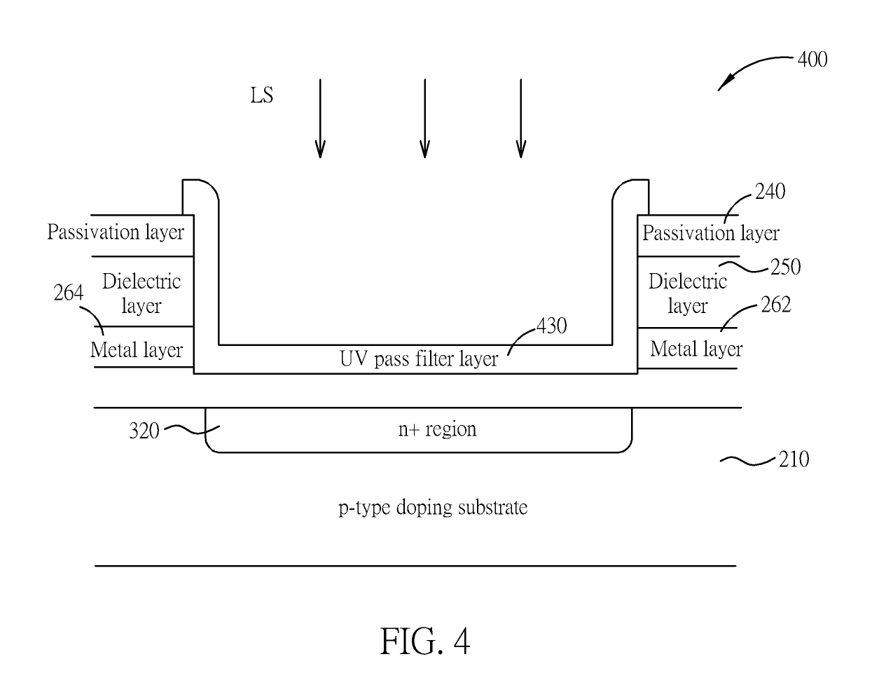

To further increase UV sensitivity of a UV sensor, the dielectric layer 250 shown in FIG. 2/FIG. 3 may be shrunk so that thickness of a part of the dielectric layer 250 above the n-type doping region (e.g. the n-well 220 or the n+ region 320) is less than thickness of another part of the dielectric layer 250 not above the n-type doping region (e.g. the n-well 220 or the n+ region 320). For example, in the embodiment shown in FIG. 3, after the passivation layer 240 is formed on the dielectric layer 250, a part of the dielectric layer 250 above the n+ region 320 may be partially removed using an etch back technique (as shown in FIG. 4). Hence, thickness of the part of the dielectric layer 250 above the n+ region 320 is less than thickness of another part of the dielectric layer 250 not above the n+ region 320. Next, as shown in FIG. 4, a UV pass filter layer 430 may be disposed above the n+ region 320. As compared to the UV sensor 300 shown in FIG. 3, the UV sensor 400 has improved UV sensitivity due to a shorter travel path of the surrounding light LS from the UV pass filter layer 430 to the PN junction between the p-type doping substrate 210 and the n+ region 320.

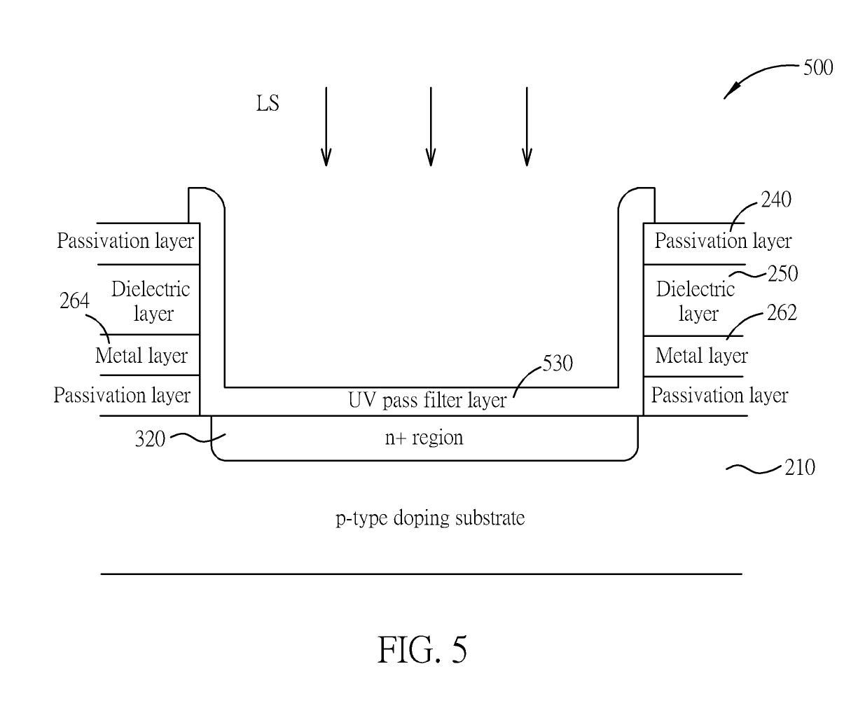

It should be noted that the aforementioned shrinking process is not limited to the etch back technique. In addition, the aforementioned shrinking process may be employed in any UV sensor implemented based on the UV sensing architecture shown in FIG. 1 (e.g. the UV sensor 200 shown in FIG. 2). Further, as shown in FIG. 5, the dielectric layer 250 above the n+ region 320 is totally removed before a UV pass filter layer 530 is formed/coated on the p-type doping substrate 210, which implements a high-sensitivity UV sensor 500.

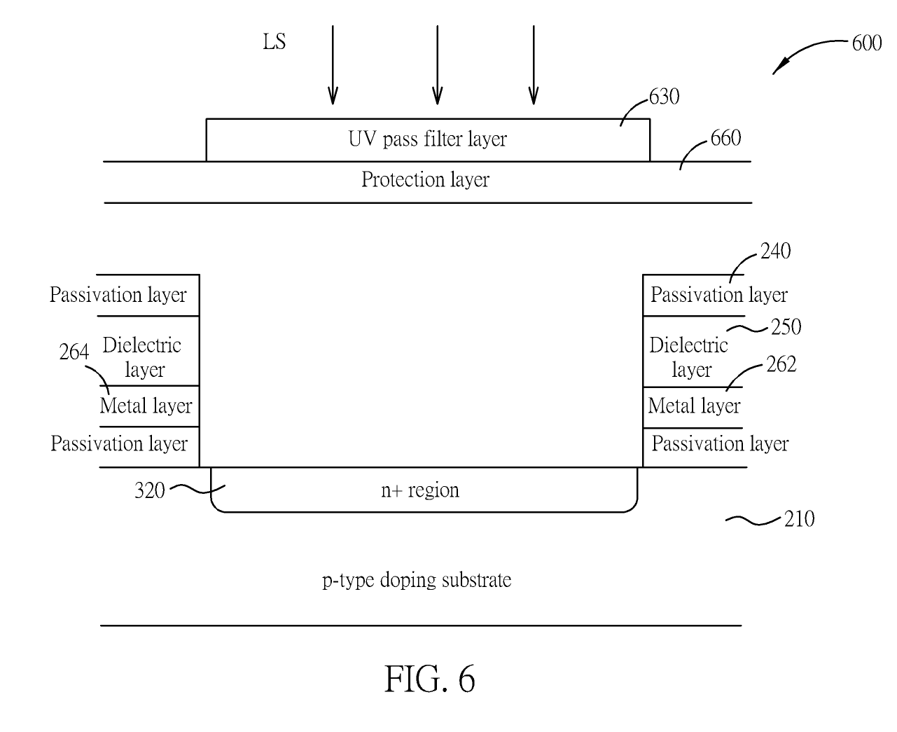

Although the UV pass filter layers shown in FIGS. 1-5 are disposed on the corresponding substrates, this is not meant to be a limitation of the present invention. Please refer to FIG. 6, which is a cross-section view of an implementation of the UV sensor 100 shown in FIG. 1. The architecture of the UV sensor 600 shown in FIG. 6 is based on the architecture of the UV sensor 500 shown in FIG. 5, wherein the main difference is that the UV sensor 600 may further include a protection layer 660 (e.g. a cover glass). The protection layer 660 is disposed at least in correspondence with the n+ region 320, and is used to protect devices and circuits on the p-type doping substrate 210 (not shown in FIG. 6). In this implementation, a UV pass filter layer 630 of the UV sensor 600 is coated on the protection layer 660. In an alternative design, the UV pass filter layer 630 maybe coated on a side of the protection layer 660, wherein the side faces the p-type doping substrate 210. In another alternative design, the UV pass filter layer 630 may be coated directly on the p-type doping substrate 210 (e.g. the UV pass filter layer 530 shown in FIG. 5). In brief, as long as UV light may pass through the protection layer, the UV pass filter layer and the dielectric layer to fall on the PN junction in the substrate, the UV pass filter layer may be located between the protection layer and dielectric layer, or the protection layer may be located between the ultraviolet pass filter layer and the dielectric layer.

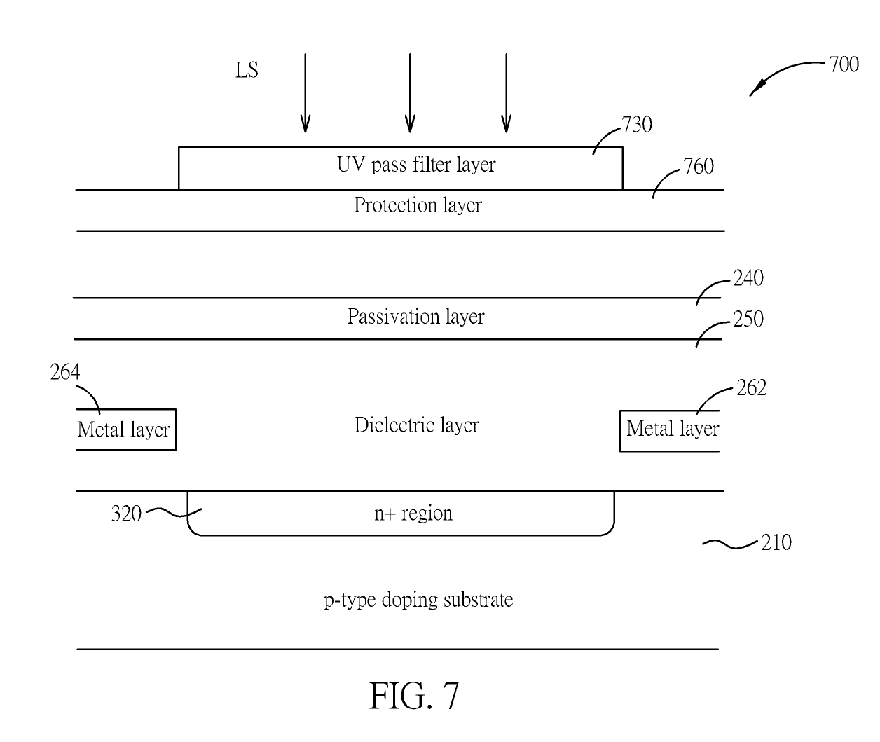

The UV sensing architecture shown in FIGS. 1-4 may employ the protection structure design shown in FIG. 6. Please refer to FIG. 7, which is a cross-section view of an implementation of the UV sensor 100 shown in FIG. 1. The architecture of the UV sensor 700 shown in FIG. 7 is based on the architecture of the UV sensor 300 shown in FIG. 3, wherein the main difference is that the UV sensor 700 may further include a protection layer 760 (e.g. a cover glass). The protection layer 760 is disposed at least in correspondence with the n+ region 320, and a UV pass filter layer 730 is coated on the protection layer 760. After reading the above paragraphs directed to FIGS. 1-6, a person skilled in the art should understand details of an embodiment where the UV pass filter layer 730 is disposed between the protection layer 760 and the p-type doping layer 210 and an embodiment where the protection layer 760 is disposed between the UV pass filter layer 730 and the p-type doping layer 210. Hence, further description is omitted here for brevity.

In view of the above, the UV sensing architectures shown in FIGS. 1-7 involve simple fabrication processes, have high sensitivity and can be integrated with other devices easily. Thus, the proposed UV sensing architecture may be employed in a variety of electronic products and/or personal portable apparatuses. Additionally, in order to further improve the UV sensitivity, the proposed UV sensing architecture may further include an auxiliary light sensor, which may compensate a sensing result obtained by the UV sensor.

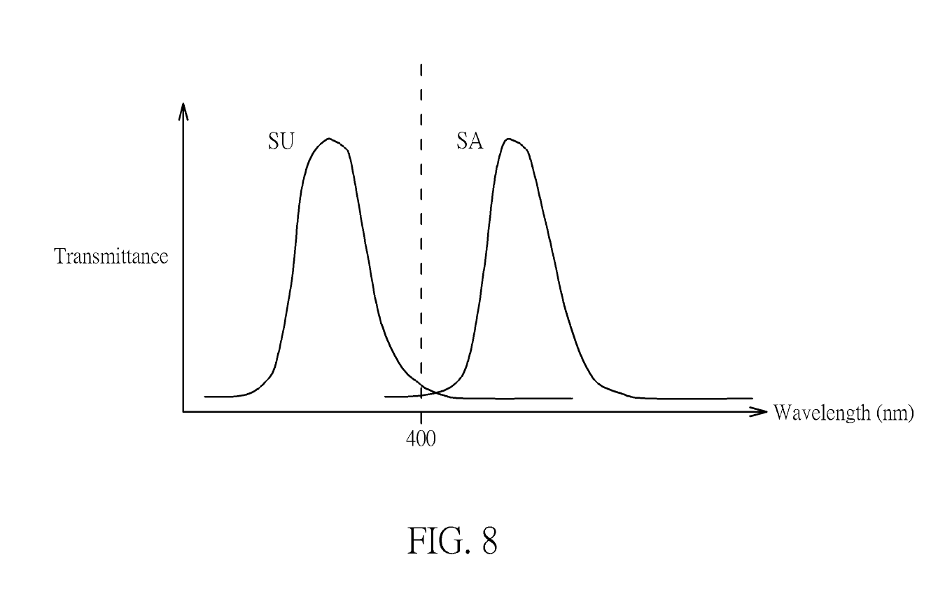

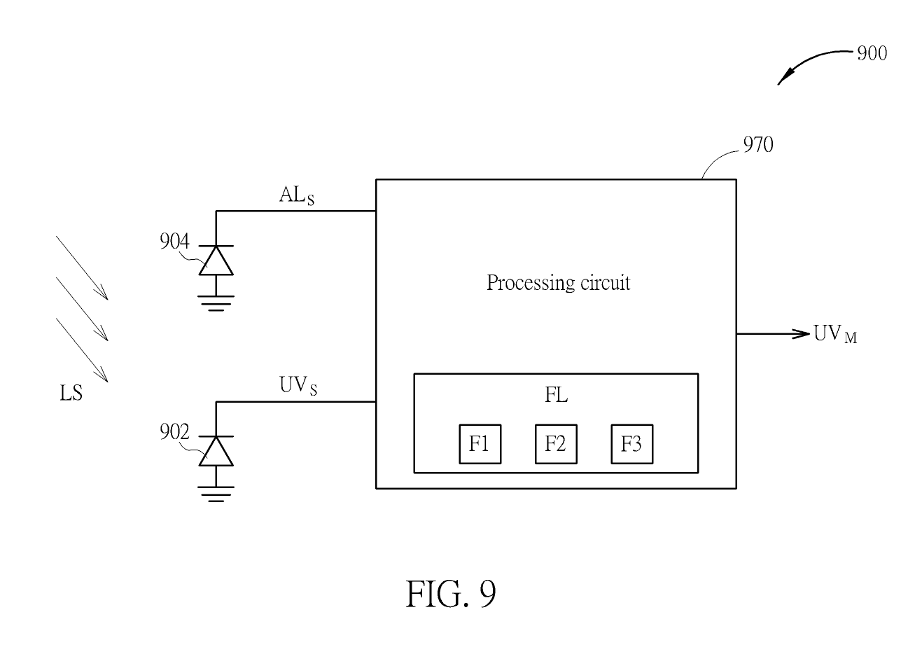

FIG. 8 illustrates a sensor spectrum of an exemplary UV sensor according to an embodiment of the present invention. As shown in FIG. 8, although the sensor spectrum SU of the UV sensor has little response to wavelengths beyond 400 nm, the UV sensor may obtain an inaccurate sensing result if a total amount of received UV radiation is insufficient compared to a total amount of received non-UV radiation (e.g. ambient light). Based on the above observation, the proposed UV sensing architecture may use a UV sensor and an auxiliary light sensor concurrently to compensate a sensing result obtained by the UV sensor. Please refer to FIG. 9, which is a block diagram illustrating an exemplary UV sensing apparatus according to an embodiment of the present invention. The UV sensing apparatus 900 may include a UV sensor 902, an auxiliary light sensor 904 and a processing circuit 970. The UV sensor 902 may generate a UV sensing result UV_{S} in response to surrounding light LS, and the auxiliary light sensor 904 may generate an auxiliary light sensing result AL_{S} in response to the surrounding light LS, wherein the UV sensor 902 may be implemented by one of the UV sensors 100-700 shown in FIGS. 1-7 or other types of UV sensors. The auxiliary light sensor 904 has a detection wave range different from a detection wave range of the UV sensor 902 so as to facilitate compensation of the UV sensing result UV_{S}. The processing circuit 970 is coupled to the UV sensor 902 and the auxiliary light sensor 904, and may perform a manipulation upon the auxiliary light sensing result AL_{S} according to the UV sensing result UV_{S} and accordingly obtain a compensated UV sensing result UV_{M}.

For example, in a case where the auxiliary light sensor 904 is implemented by an ambient light sensor (having a sensor spectrum SA shown in FIG. 8), the processing circuit 970 may perform a manipulation upon the UV sensing result UV_{S} and the auxiliary light sensing result AL_{S}, subtract ambient light sensing information from the UV sensing result UV_{S} (e.g. the response beyond 400 nm), and accordingly estimate/obtain UV light information in the environment (UV intensity of the surrounding light LS).

In this embodiment, the processing circuit 970 may obtain the compensated UV sensing result according to the following expression:

$${UV}_{M} = \frac{( {UV}_{S} - B \times {AL}_{S} )}{A} ,$$

where A is a UV sensing parameter, and B is an auxiliary light sensing parameter. As the UV sensing parameter A and the auxiliary light sensing parameter B are known, the processing circuit 970 may obtain the compensated UV sensing result UV_{M} according to the UV sensing result UV_{S} and the auxiliary light sensing result AL_{S}.

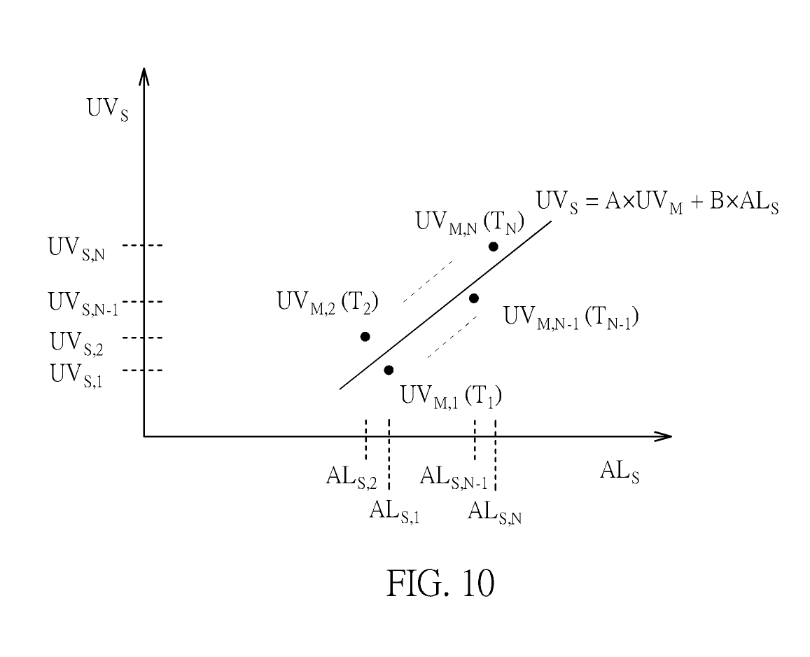

In one implementation, the UV sensing parameter A and the auxiliary light sensing parameter B may be determined with the aid of an ultraviolet meter (UV meter) in advance. Please refer to FIG. 10 in conjunction with FIG. 9. FIG. 10 is a diagram illustrating determination of a UV sensing parameter and an auxiliary light sensing parameter according to an embodiment of the present invention. First, the UV sensor 902 may perform sensing operations at points in time T₁−T_{N} (N is an integer greater than 1) to obtain a plurality of UV sensing values UV_{S,1}−UV_{S,N}, and the auxiliary light sensor 904 may perform sensing operations at the points in time T₁−T_{N} to obtain a plurality of auxiliary light sensing values AL_{S,1}−AL_{S,N}. Next, the processing circuit 970 may determine the UV sensing parameter A and the auxiliary light sensing parameter B of a linear approximation UV_{S}=A×UV_{M}+B×AL_{S} according to the UV sensing values UV_{S,1}−UV_{S,N}, the auxiliary light sensing values AL_{S,1}−AL_{S,N}, and a plurality of measured values UV_{M,1}−UV_{M,N} obtained by a UV meter (not shown in FIG. 9) at the points in time T₁−T_{N}. As a person skilled in the art should understand that the UV sensing parameter A and the auxiliary light sensing parameter B may be determined by substituting the UV sensing values UV_{S,1}−UV_{S,N} for UV_{S}, the auxiliary light sensing values AL_{S,1}−AL_{S,N} for AL_{S}, and the measured values UV_{M,1}−UV_{M,N} for UV_{M} in the linear approximation UV_{S}=A×UV_{M}+B×AL_{S}, further description is omitted here for brevity.

The above linear approximation is for illustrative purposes only, and is not meant to be a limitation of the present invention. In an alternative design, the processing circuit 970 may determine coefficients (sensing parameters) for a non-linear approximation according to the measured values UV_{M,1}−UV_{M,N}, the UV sensing values UV_{S,1}−UV_{S,N} and the auxiliary light sensing values AL_{S,1}−AL_{S,N}. In another alternative design, the processing circuit 970 may determine different manipulations (e.g. an expression, an approximation function or an approximate straight line) according to different UV sensing results (sensed amounts of UV radiation) and/or different auxiliary light sensing results (sensed amounts of auxiliary light).

By way of example but not limitation, the processing circuit 970 may determine an expression/approximation function/approximate straight line according to a ratio between the UV sensing result UV_{S} and the auxiliary light sensing result AL_{S} (e.g. a ration between a UV sensing value and an auxiliary light sensing value). In one implementation, the processing circuit 970 may store an expression list FL, wherein the expression list FL may include different mathematical expressions F1-F3, and the mathematical expressions F1-F3 correspond to different weather conditions (sunny, cloudy and rainy conditions) respectively. Specifically, if the ratio between the sensed amount of UV radiation and the sensed amount of auxiliary light falls within a first range (meaning that the current weather is sunny), the processing circuit 970 may determine the mathematical expression F1 to be used as the corresponding approximation function; if the ratio between the sensed amount of UV radiation and the sensed amount of auxiliary light falls within a second range (meaning that the current weather is cloudy), the processing circuit 970 may determine the mathematical expression F2 to be used as the corresponding approximation function; if the ratio between the sensed amount of UV radiation and the sensed amount of auxiliary light falls within a third range (meaning that the current weather is rainy), the processing circuit 970 may determine the mathematical expression F3 to be used as the corresponding approximation function. Next, the processing circuit 970 may obtain the compensated UV sensing result UV_{M} according to sensing parameter(s) of the determined expression.

In view of the above, as long as a detection wave range of the auxiliary light sensor 904 is different from a detection wave range of the UV sensor 902, the obtained UV sensing result can be compensated accordingly. Thus, the auxiliary light sensor 904 may be implemented by other types of sensors (e.g. an infrared light sensor).

It should be noted that the auxiliary light sensor 904 and the UV sensor 902 may be implemented in the same fabrication process. By way of example but not limitation, the architecture of the auxiliary light sensor 904 may be identical to the architecture of the UV sensor 100 shown in FIG. 1, wherein the main difference is that the auxiliary light sensor 904 does not include the UV pass filter layer 130. In another example, the auxiliary light sensor 904 may include a pass filter layer different from the UV pass filter layer 130. In view of this, the UV sensing apparatus 900 may not only increase the UV sensitivity further but also involve simple fabrication processes and ease of integration.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An ultraviolet sensor, comprising:
a p-type doping substrate;
an n-type doping region, formed on a surface of the p-type doping substrate; and
an ultraviolet pass filter layer, disposed in correspondence with the n-type doping region, wherein the n-type doping region is located between the ultraviolet pass filter layer and the p-type doping substrate.

2. The ultraviolet sensor of claim 1, wherein the n-type doping region is an n-well.

3. The ultraviolet sensor of claim 1, wherein the n-type doping region is an n+ region.

4. The ultraviolet sensor of claim 1, further comprising:
a protection layer, disposed at least in correspondence with the n-type doping region, wherein the ultraviolet pass filter layer is located between the protection layer and the p-type doping substrate, or the protection layer is located between the ultraviolet pass filter layer and the p-type doping substrate.

5. The ultraviolet sensor of claim 1, further comprising:
a dielectric layer, formed between the ultraviolet pass filter layer and the p-type doping substrate, wherein the dielectric layer is shrunk so that thickness of a part of the dielectric layer above the n-type doping region is less than thickness of another part of the dielectric layer not above the n-type doping region.

6. The ultraviolet sensor of claim 5, further comprising:
a protection layer, disposed at least in correspondence with the n-type doping region, wherein the ultraviolet pass filter layer is located between the protection layer and the dielectric layer, or the protection layer is located between the ultraviolet pass filter layer and the dielectric layer.

7. An ultraviolet sensing apparatus, comprising:
an ultraviolet sensor, arranged for generating an ultraviolet sensing result in response to surrounding light;
an auxiliary light sensor, arranged for generating an auxiliary light sensing result in response to the surrounding light, wherein a detection wave range of the auxiliary light sensor is different from a detection wave range of the ultraviolet sensor; and
a processing circuit, coupled to the ultraviolet sensor and the auxiliary light sensor, the processing arranged for performing a manipulation upon the auxiliary light sensing result according to the ultraviolet sensing result, and accordingly obtaining a compensated ultraviolet sensing result.

8. The ultraviolet sensing apparatus of claim 7, wherein the manipulation is expressed by
$${UV}_{M} = \frac{( {UV}_{S} - B \times {AL}_{S} )}{A} ,$$
UV_{M} is the compensated ultraviolet sensing result, UV_{S} is the ultraviolet sensing result, AL_{S} is the auxiliary light sensing result, A is an ultraviolet sensing parameter, and B is an auxiliary light sensing parameter.

9. The ultraviolet sensing apparatus of claim 7, wherein the processing circuit determines the manipulation according to a ratio between the ultraviolet sensing result and the auxiliary light sensing result.

10. The ultraviolet sensing apparatus of claim 7, wherein the auxiliary light sensor is an ambient light sensor or an infrared light sensor.

11. A sensing method for obtaining a compensated ultraviolet sensing result, comprising:
utilizing an ultraviolet sensor to generate an ultraviolet sensing result in response to surrounding light;
utilizing an auxiliary light sensor to generate an auxiliary light sensing result in response to the surrounding light, wherein a detection wave range of the auxiliary light sensor is different from a detection wave range of the ultraviolet sensor; and
performing a manipulation upon the auxiliary light sensing result according to the ultraviolet sensing result, and accordingly obtaining the compensated ultraviolet sensing result.

12. The sensing method of claim 10, wherein the manipulation is expressed by
$${UV}_{M} = \frac{( {UV}_{S} - B \times {AL}_{S} )}{A} ,$$
UV_{M} is the compensated ultraviolet sensing result, UV_{S} is the ultraviolet sensing result, AL_{S} is the auxiliary light sensing result, A is an ultraviolet sensing parameter, and B is an auxiliary light sensing parameter.

13. The sensing method of claim 10, wherein the step of performing a manipulation upon the auxiliary light sensing result according to the ultraviolet sensing result comprises:
determining the manipulation according to a ratio between the ultraviolet sensing result and the auxiliary light sensing result.

14. The sensing method of claim 10, wherein the auxiliary light sensor is an ambient light sensor or an infrared light sensor.
